(19) United States
(12) Patent Application Publication
(10) Pub. No.: US 2023/0290888 A1
(43) Pub. Date: Sep. 14, 2023

(54) SEMICONDUCTOR ELEMENT AND SEMICONDUCTOR DEVICE

(71) Applicant: FLOSFIA INC., Kyoto (JP)

(72) Inventors: Hideaki YANAGIDA, Kyoto (JP); Shogo MIZUMOTO, Kyoto (JP); Hiroyuki ANDO, Kyoto (JP); Yusuke MATSUBARA, Kyoto (JP)

(21) Appl. No.: 18/106,095

(22) Filed: Feb. 6, 2023

Related U.S. Application Data
(63) Continuation-in-part of application No. PCT/JP2021/029578, filed on Aug. 10, 2021.

(30) Foreign Application Priority Data
Aug. 7, 2020 (JP) 2020-134996

(51) Int. Cl. H01L 29/872; H01L 29/808; H01L 29/24; H01L 29/47; H01L 29/04

(52) U.S. Cl. CPC H01L 29/872; H01L 29/808; H01L 29/24; H01L 29/47; H01L 29/04

(57) ABSTRACT

Provided is a semiconductor element including at least, a semiconductor layer including a crystalline oxide semiconductor as a major component; an electrode layer laminated on the semiconductor layer; and a conductive substrate laminated on the electrode layer directly or with another layer in between, the conductive substrate containing at least a first metal selected from the metals in group 11 in the periodic table and a second metal different from the first metal in coefficient of liner thermal expansion.

### CROSS REFERENCE TO RELATED APPLICATION

This application is a continuation-in-part application of International Patent Application No. PCT/JP2021/029578 (Filed on Aug. 10, 2021), which claims the benefit of priority from Japanese Patent Application No. 2020-134996 (filed on Aug. 7, 2020).

The entire contents of the above applications, which the present application is based on, are incorporated herein by reference.

### 1. FIELD OF THE INVENTION

The present disclosure relates to a semiconductor element that is useful as a power device or the like.

### 2. DESCRIPTION OF THE RELATED ART

As next-generation switching elements capable of achieving high voltage resistance, low loss, and high heat resistance, attention has been focused on semiconductor devices using gallium oxide (Ga₂O₃) having a wide bandgap, which are expected to be applied to power semiconductor devices, such as inverters. Moreover, given the wide bandgap, the devices find prospective application as light receiving and emitting devices, such as LEDs and sensors. The bandgap of the gallium oxide is controllable by turning it into a mixed crystal with indium or aluminum alone or the combination thereof, and InAlGaO-based semiconductors constitute an extremely attractive family of materials. Here, InAlGaO-based semiconductors indicate InₓAl_{Y}Ga_{Z}O₃ (0≤X≤2, 0≤Y≤2, 0≤Z≤2, X+Y+Z=1.5 to 2.5) and may be regarded as a family of materials including gallium oxide.

### SUMMARY OF THE INVENTION

According to an example of the present disclosure, there is provided a semiconductor element including at least, a semiconductor layer including a crystalline oxide semiconductor as a major component; an electrode layer laminated on the semiconductor layer; and a conductive substrate laminated on the electrode layer directly or with another layer in between, the conductive substrate containing at least a first metal selected from the metals in group 11 in the periodic table and a second metal different from the first metal in coefficient of liner thermal expansion.

Thus, a semiconductor element of the present disclosure is excellent in electrical characteristics, including forward characteristics.

### BRIEF DESCRIPTION OF THE DRAWINGS

FIG. 1 is a view showing an example of a multilayer body used in an embodiment of the present disclosure.

FIG. 2 is a view showing an example of a bonded multilayer body used in an embodiment of the present disclosure.

FIG. 3 is a view showing an example of a semiconductor structure used in an embodiment of the present disclosure.

FIG. 4 is a view schematically showing a suitable aspect of a Schottky barrier diode (SBD) of the present disclosure.

FIG. 5 is a view schematically showing a suitable aspect of a Schottky barrier diode (SBD) of the present disclosure.

FIG. 6 is a view schematically showing a suitable example of a metal-oxide semiconductor field-effect transistor (MOSFET) of the present disclosure.

FIGS. 7A-7C are schematic views for describing a part of a manufacturing process of the metal-oxide semiconductor field-effect transistor (MOSFET) of FIG. 6 with FIG. 7A being a schematic view describing the multilayer body before forming the trench grooves, FIG. 7B being a schematic view describing the multilayer body in which the trench grooves are formed, and FIG. 7C being a schematic view describing the multilayer body having the trench grooves in which the gate insulation film and the gate electrode are formed.

FIG. 8 is a view schematically showing a suitable example of a static induction transistor (SIT) of the present disclosure.

FIG. 9 is a view schematically showing a suitable example of a Schottky barrier diode (SBD) of the present disclosure.

FIG. 10 is a view schematically showing a suitable example of a metal-oxide semiconductor field-effect transistor (MOSFET) of the present disclosure.

FIG. 11 is a view schematically showing a suitable example of a junction field-effect transistor (JFET) of the present disclosure.

FIG. 12 is a configuration diagram of a mist CVD device used in an example of the present disclosure.

FIG. 13 is a graph showing a result of an IV measurement in an example, with the axis of ordinate showing a current (A) and the axis of abscissa showing a voltage (V).

FIG. 14 is a graph showing a result of an IV measurement in a comparative example, with the axis of ordinate showing a current (A) and the axis of abscissa showing a voltage (V).

FIG. 15 is a view schematically showing a suitable example of a semiconductor device.

FIG. 16 is a block configuration diagram showing an example of a control system adopting a semiconductor device according to an embodiment of the present disclosure.

FIG. 17 is a circuit diagram showing an example of a control system adopting a semiconductor device according to an embodiment of the present disclosure.

FIG. 18 is a block configuration diagram showing an example of a control system adopting a semiconductor device according to an embodiment of the present disclosure.

FIG. 19 is a circuit diagram showing an example of a control system adopting a semiconductor device according to an embodiment of the present disclosure.

FIG. 20 is a chart showing a result of a heat resistance simulation in an embodiment of the present disclosure.

FIG. 21 is a chart showing a result of a heat resistance simulation in an embodiment of the present disclosure.

FIG. 22 is a chart showing a result of a heat resistance simulation in an embodiment of the present disclosure.

FIG. 23 is a view showing a preferable aspect of a conductive substrate (Cu—Mo laminated substrate) in an embodiment of the present disclosure.

FIG. 24 is a chart showing a result of measurement of warpage in an embodiment of the present disclosure.

### DETAILED DESCRIPTION

The inventors of present disclosure found out that when a conductive substrate containing at least a first metal selected from the metals in group 11 in the periodic table and a second metal different from the first metal in coefficient of linear thermal expansion was used in manufacturing (preprocessing) of a semiconductor element that used a semiconductor layer including a crystalline oxide semiconductor as a major component, not only did the adhesion to an electrode and a bonding layer in the obtained semiconductor element improve, but also warpage was mitigated and the obtained semiconductor element had better electrical characteristics, including forward characteristics. As a result of further studies, it was found that a semiconductor element including a semiconductor layer including a crystalline oxide semiconductor as a major component, an electrode layer laminated on the semiconductor layer, and a conductive substrate laminated on the electrode layer directly or with another layer in between, with the conductive substrate containing at least a first metal selected from the metals in group 11 in the periodic table and a second metal different from the first metal in coefficient of linear thermal expansion had excellent electrical characteristics, including forward characteristics and was capable of solving the above-described conventional problems all at once.

Embodiments of the present disclosure will be described below with reference to the accompanying drawings. In the following description, the same parts and components are designated by the same reference numerals. The present embodiment includes, for example, the following disclosures.

### [Structure 1]

A semiconductor element including at least: a semiconductor layer including a crystalline oxide semiconductor as a major component; an electrode layer laminated on the semiconductor layer; and a conductive substrate laminated on the electrode layer directly or with another layer in between, the conductive substrate containing at least a first metal selected from the metals in group 11 in the periodic table and a second metal different from the first metal in coefficient of liner thermal expansion.

### [Structure 2]

The semiconductor element according to [Structure 1], wherein the first metal is copper.

### [Structure 3]

The semiconductor element according to [Structure 1] or [Structure 2], wherein the second metal includes a metal in group 6 in the periodic table.

### [Structure 4]

The semiconductor element according to [Structure 3], wherein the metal in group 6 in the periodic table is molybdenum.

### [Structure 5]

The semiconductor element according to any one of [Structure 1] to [Structure 4], wherein the conductive substrate has a multilayer structure in which at least one layer including the first metal and at least one layer including the second metal are laminated.

### [Structure 6]

The semiconductor element according to [Structure 5], wherein a top layer and/or a bottom layer of the multilayer structure includes the first metal.

### [Structure 7]

The semiconductor element according to any one of [Structure 1] to [Structure 6], wherein the crystalline oxide semiconductor includes at least one metal selected from aluminum, indium, and gallium.

### [Structure 8]

The semiconductor element according to any one of [Structure 1] to [Structure 7], wherein the crystalline oxide semiconductor includes at least gallium.

### [Structure 9]

The semiconductor element according to any one of [Structure 1] to [Structure 8], further including another electrode layer on a surface facing a surface of the semiconductor layer on which the electrode layer is laminated.

### [Structure 10]

The semiconductor element according to any one of [Structure 1] to [Structure 9], wherein the semiconductor element is a power device.

### [Structure 11]

A semiconductor device formed by joining at least a semiconductor element to a lead frame, a circuit board, or a heat dissipation substrate by means of a joint member, wherein the semiconductor element is the semiconductor element according to any one of [Structure 1] to [Structure 10].

### [Structure 12]

A power converter that uses the semiconductor device according to [Structure 11].

### [Structure 13]

A control system that uses the semiconductor device according to [Structure 11].

A semiconductor element of the present disclosure is a semiconductor element including at least a semiconductor layer including a crystalline oxide semiconductor as a major component, an electrode layer laminated on the semiconductor layer, and a conductive substrate laminated on the electrode layer directly or with another layer in between, wherein the conductive substrate contains at least a first metal selected from the metals in group 11 in the periodic table and a second metal different from the first metal in coefficient of linear thermal expansion.

In an embodiment of the present disclosure, the semiconductor element may be suitably manufactured by, for example, a manufacturing method including (1) laminating the semiconductor layer on a base substrate directly or with another layer in between, then (2) forming an electrode layer on the semiconductor layer, and then (3) laminating the conductive substrate on the electrode layer, via a conductive bonding layer if desired, and removing the base substrate using a commonly known method. In the following, examples of the major steps (1) to (3) in manufacturing the semiconductor element will be described in more detail using the drawings.

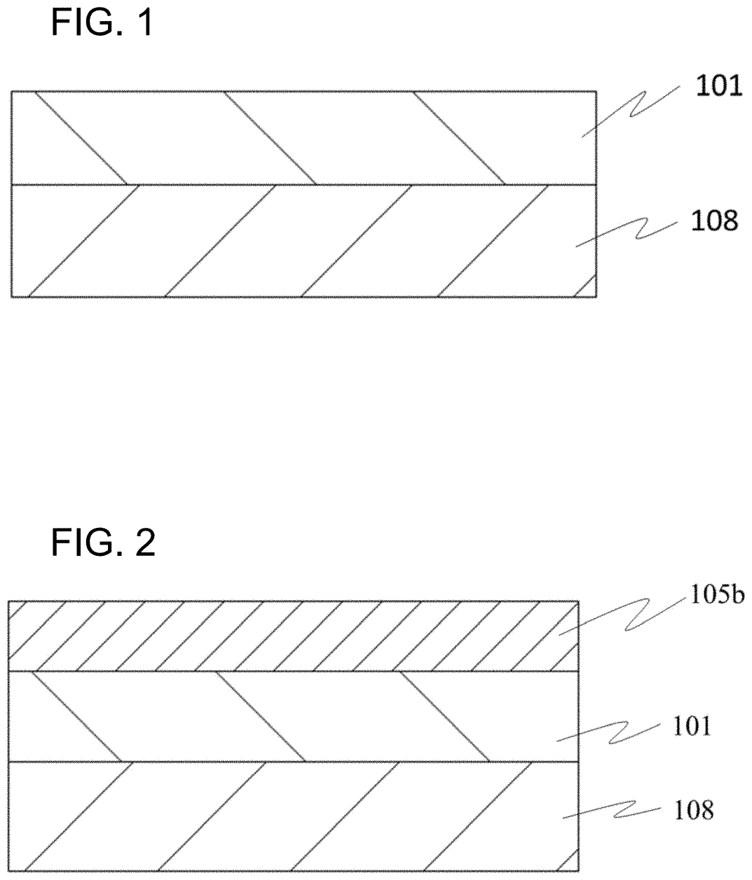

In step (1), the semiconductor layer is laminated on the base substrate directly or with another layer in between. By step (1), for example, a multilayer body as shown in FIG. 1 may be obtained. The multilayer body shown in FIG. 1 has a crystalline semiconductor 101 laminated on a base substrate 108. In the present disclosure, the crystalline semiconductor film 101 obtained by step (1) is usable as the semiconductor layer (hereinafter also referred to as a “semiconductor film”). In the following, step (1) will be described.

(Base Substrate)

The base substrate is not particularly limited as long as it has a plate shape and serves as a support for the semiconductor film. The base substrate may be an insulator substrate, a semiconductor substrate, a metal substrate, or a conductive substrate, but it is preferable that the base substrate be an insulator substrate and it is also preferable that it be a substrate having a metal film on its surface. Examples of the base substrates include a base substrate including a substrate material having a corundum structure as a major component, a base substrate including a substrate material having a β-gallia structure as a major component, and a base substrate including a substrate material having a hexagonal crystalline structure as a major component. Here, the “major component” means that the substrate material having the specific crystalline structure is included preferably 50% or more, more preferably 70% or more, further preferably 90% or more, and may also be included 100%, in atomic ratio relative to all the components of the substrate material.

The substrate material is not particularly limited unless it interferes with the present disclosure, and may be a commonly known one. Suitable examples of substrate materials having the aforementioned corundum structure include α-Al₂O₃ (sapphire substrate) and α-Ga₂O₃, and more suitable examples include an a-plane sapphire substrate, an m-plane sapphire substrate, an r-plane sapphire substrate, a c-plane sapphire substrate, and a-type gallium oxide substrate (a-plane, m-plane, or r-plane). Examples of base substrates having a substrate material with a β-gallia structure as a major component include a β-Ga₂O₃ substrate, and a mixed crystal substrate including Ga₂O₃ and Al₂O₃, with Al₂O₃ being more than 0 wt % and not more than 60 wt %. Examples of base substrates having a substrate material with a hexagonal crystalline structure as a major component include an SiC substrate, a ZnO substrate, and a GaN substrate.

The semiconductor layer is not particularly limited as long as it includes a crystalline oxide semiconductor as a major component. The crystalline structure of the crystalline oxide semiconductor is also not particularly limited unless it interferes with the present disclosure. Examples of the crystalline structure of the crystalline oxide semiconductor include a corundum structure, a β-gallia structure, a hexagonal crystalline structure (e.g., an ε-type structure), an orthorhombic structure (e.g., a κ-type structure), a cubic structure, and a tetragonal structure. In an embodiment of the present disclosure, the crystalline oxide semiconductor preferably has a corundum structure, a β-gallia structure, or a hexagonal crystalline structure (e.g., an ε-type structure), and more preferably has a corundum structure. Examples of the crystalline oxide semiconductor include a metal oxide including one type or two or more types of metals selected from aluminum, gallium, indium, iron, chromium, vanadium, titanium, rhodium, nickel, cobalt, and iridium. In an embodiment of the present disclosure, the crystalline oxide semiconductor preferably contains at least one type of metal selected from aluminum, indium, and gallium, more preferably includes at least gallium, and most preferably is α-Ga₂O₃ or a mixed crystal thereof. The “major component” means that the crystalline oxide semiconductor is included preferably 50% or more, more preferably 70% or more, even more preferably 90% or more, and may also be included 100%, in atomic ratio relative to all the components of the semiconductor layer. The thickness of the semiconductor layer is not particularly limited and may be 1 μm or smaller or may be 1 μm or larger, but is preferably 1 μm or larger in an embodiment of the present disclosure. The surface area of the semiconductor layer is not particularly limited and may be 1 mm² or larger or may be 1 mm² or smaller, but is preferably 10 mm² to 300 cm² and more preferably 100 mm² to 100 cm². While the semiconductor layer is usually a monocrystal, it may also be a polycrystal. The semiconductor layer is preferably a multilayer film including at least a first semiconductor layer and a second semiconductor layer, and when a Schottky electrode is provided on the first semiconductor layer, the semiconductor layer is also preferably a multilayer film in which the carrier density of the first semiconductor layer is lower than the carrier density of the second semiconductor layer. In this case, the second semiconductor layer usually includes a dopant, and the carrier density of the semiconductor layer may be appropriately set by adjusting the amount of doping.

The semiconductor layer preferably includes a dopant. The dopant is not particularly limited and may be a commonly known one. Examples of the dopants include n-type dopants, such as tin, germanium, silicon, titanium, zirconium, vanadium, and niobium, and p-type dopants, such as magnesium, calcium, and zinc. In an embodiment of the present disclosure, the n-type dopant is preferably Sn, Ge, or Si. The content of the dopant in the composition of the semiconductor layer is preferably 0.00001 at. % or higher, more preferably 0.00001 at. % to 20 at. %, and most preferably 0.00001 at. % to 10 at. %. More specifically, the concentration of the dopant may be usually about 1×10¹⁶/cm³ to 1×10²²/cm³, and the concentration of the dopant may be set to a low concentration, for example, about 1×10¹⁷/cm³ or lower. Further, according to the present disclosure, the dopant may be contained at a high concentration of about 1×10²⁰/cm³ or higher. In an embodiment of the present disclosure, it is preferable that the dopant be contained at a carrier concentration of 1×10¹⁷/cm³ or higher.

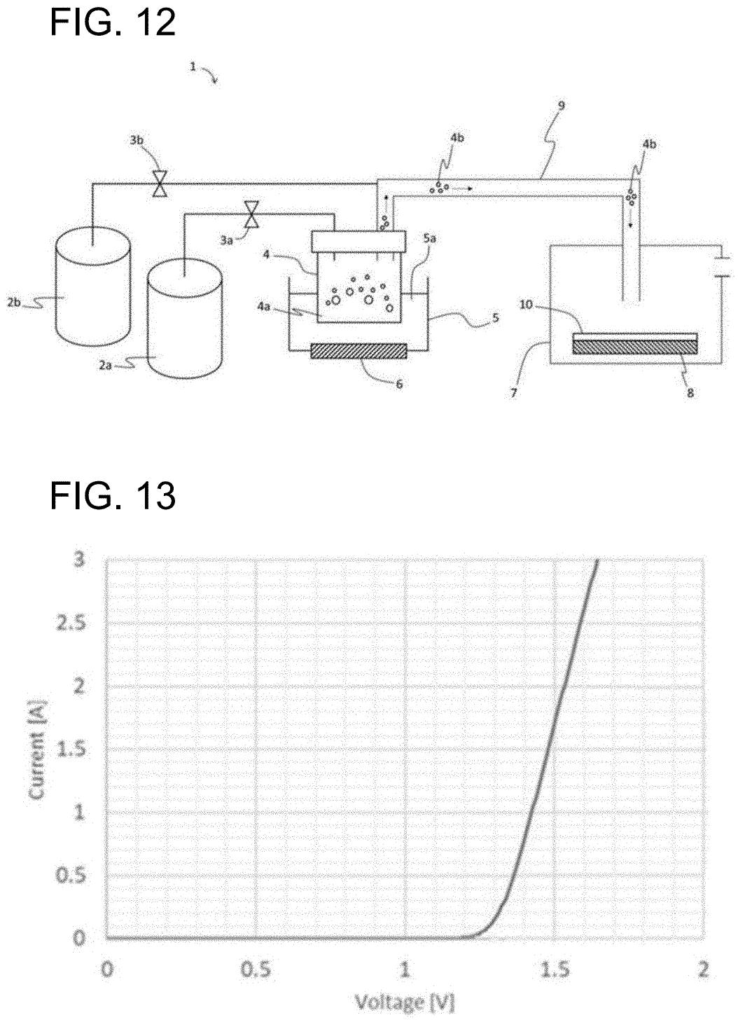

The semiconductor layer may be formed using a commonly known method. Examples of methods of forming the semiconductor layer include a CVD method, an MOCVD method, an MOVPE method, a mist CVD method, a mist epitaxy method, an MBE method, an HVPE method, a pulse growth method, and an ALD method. In an embodiment of the present disclosure, the method of forming the semiconductor layer is preferably a mist CVD method or a mist epitaxy method. In the mixt CVD method or the mist epitaxy method, the semiconductor layer is formed, for example, using the mist CVD device shown in FIG. 12, by atomizing a raw material solution (atomization step), suspending droplets, conveying, after atomization, the obtained atomized droplets onto a substrate by a carrier gas (conveying step), and then subjecting the atomized droplets to a thermal reaction inside a deposition chamber to laminate a semiconductor film including a crystalline oxide semiconductor as a major component on the substrate (deposition step).

(Atomization Step)

In the atomization step, the raw material solution is atomized. The method of atomizing the raw material solution is not particularly limited as long as it is able to atomize the raw material solution, and may be a commonly known method. In an embodiment of the present disclosure, however, a method of atomization using ultrasonic waves is preferable. Atomized droplets obtained using ultrasonic waves are preferable as they have a zero initial speed and are suspended in the air, and is very suitable as they are mist that is conveyable as a gas by being suspended in space instead of, for example, being blown like spray, so that damage due to collision energy does not occur. While the size of droplets is not particularly limited and the droplets may be droplets of about a few millimeters, the size is preferably 50 μm or smaller and more preferably 100 nm to 10 μm.

(Raw Material Solution)

The raw material solution is not particularly limited as long as it is able to be atomized or turned into droplets and includes a raw material capable of forming a semiconductor film, and may be an inorganic material or may be an organic material. In an embodiment of the present disclosure, the raw material is preferably metal or metal compound, and more preferably includes one type or two or more types of metals selected from aluminum, gallium, indium, iron, chromium, vanadium, titanium, rhodium, nickel, cobalt, and iridium.

In an embodiment of the present disclosure, as the raw material solution, one obtained by dissolving or dispersing the metal in the form of a complex or salt into an organic solvent or water may be suitably used. Examples of forms of a complex include an acetylacetonato complex, a carbonyl complex, an ammine complex, and a hydride complex. Examples of forms of salt include organometallic salt (e.g., metal acetate, metal oxalate, and metal citrate), metal sulfate, metal nitrate, metal phosphate, and halide metal salt (e.g., chloride metal salt, bromide metal salt, and iodide metal salt).

It is preferable that an additive, such as a hydrohalic acid or an oxidant, be mixed into the raw material solution. Examples of hydrohalic acids include hydrobromic acid, hydrochloric acid, and hydriodic acid, and, in particular, a hydrobromic acid or a hydriodic acid is preferable because it allows generation of abnormal grains to be more efficiently reduced. Examples of the oxidants include peroxide such as hydrogen peroxide (H₂O₂), sodium peroxide (Na₂O₂), barium peroxide (BaO₂), and benzoyl peroxide (C₆H₅CO)₂O₂, and organic peroxide such as hypochlorous acid (HClO), perchloric acid, nitric acid, ozone water, peracetic acid, and nitrobenzene.

The raw material solution may include a dopant. Including a dopant in the raw material solution allows favorable doping. The dopant is not particularly limited unless it interferes with the present disclosure. Examples of the dopants include n-type dopants such as tin, germanium, silicon, titanium, zirconium, vanadium, and niobium, and p-type dopants, such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N, and P. The content of the dopant is appropriately set by using a calibration curve that shows a relationship of the concentration of a dopant in a raw material relative to a desired carrier density.

The solvent of the raw material solution is not particularly limited, and may be an inorganic solvent such as water, may be an organic solvent such as alcohol, or may be a mixed solvent of an inorganic solvent and an organic solvent. In an embodiment of the present disclosure, the solvent preferably includes water, and is more preferably water or a mixed solvent of water and alcohol.

(Conveying Step)

In the conveying step, the atomized droplets are conveyed into the deposition chamber by a carrier gas. The carrier gas is not particularly limited unless it interferes with the present disclosure, and suitable examples include inert gases such as oxygen, ozone, nitrogen, and argon, and reducing gases such as a hydrogen gas and a forming gas. The type of carrier gas may be one type, but may also be two or more types, and, for example, a dilution gas (e.g., a tenfold dilution gas) with a reduced flow rate may be additionally used as a second carrier gas. There may be not only one but also two or more carrier gas supply points. While the flow rate of the carrier gas is not particularly limited, it is preferably 0.01 to 20 L/min and more preferably 1 to 10 L/min. In the case of a dilution gas, the flow rate of the dilution gas is preferably 0.001 to 2 L/min and more preferably 0.1 to 1 L/min.

(Deposition Step)

In the deposition step, the atomized droplets are subjected to a thermal reaction inside the deposition chamber to thereby deposit the semiconductor film on the substrate. In the thermal reaction, it suffices that the atomized droplets react by heat, and the reaction conditions etc. are also not particularly limited unless they interfere with the present disclosure. In this step, the thermal reaction usually occurs at a temperature equal to or higher than the evaporation temperature of the solvent, and the temperature is preferably equal to or lower than not too high a temperature (e.g., 1000° C.), more preferably 650° C. or lower, and most preferably 300° C. to 650° C. Unless it interferes with the present disclosure, the thermal reaction may occur in any atmosphere among vacuum, a non-oxygen atmosphere (e.g., an inert gas atmosphere), a reducing gas atmosphere, and an oxygen atmosphere, and preferably occur in an inert gas atmosphere or an oxygen atmosphere. While the thermal reaction may occur under any conditions among atmospheric pressure conditions, pressurized conditions, and depressurized conditions, in an embodiment of the present disclosure, it preferably occur under atmospheric pressure conditions. The thickness of the film may be set by adjusting the deposition time.

In an embodiment of the present disclosure, annealing treatment may be performed after the deposition step. The temperature of the annealing treatment is not particularly limited unless it interferes with the present disclosure, and it is usually 300° C. to 650° C., and preferably 350° C. to 550° C. The time of the annealing treatment is usually one minute to 48 hours, preferably 10 minutes to 24 hours, and more preferably 30 minutes to 12 hours. The annealing treatment may be performed in any atmosphere unless it interferes with the present disclosure. It may be performed in a non-oxygen atmosphere or an oxygen atmosphere. Examples of non-oxygen atmospheres include an inert gas atmosphere (e.g., a nitrogen atmosphere) and a reducing gas atmosphere, and in an embodiment of the present disclosure, an inert gas atmosphere is preferable and a nitrogen atmosphere is more preferable.

In an embodiment of the present disclosure, the semiconductor film may be provided directly on the base substrate, or the semiconductor film may be provided with another layer in between, such as a stress relieving layer (e.g., a buffer layer or an ELO layer) or a sacrificial release layer. The method of forming each layer is not particularly limited and may be a commonly known method, and in an embodiment of the present disclosure, a mist CVD method is preferable.

In step (2), an electrode layer 105b is formed on the semiconductor layer 101. By step (2), for example, the multilayer body as shown in FIG. 2 may be obtained. The multilayer body of FIG. 2 is composed of the base substrate 108, the semiconductor layer 101, and the electrode layer 105b.

The electrode layer may be any layer having conductivity and is not particularly limited unless it interferes with the present disclosure. The material composing the electrode layer may be a conductive inorganic material or may be a conductive organic material. In an embodiment of the present disclosure, the material of the electrode is preferably metal. Suitable examples of metals include at least one type of metal selected from group 4 to group 10 in the periodic table. Examples of metals in group 4 in the periodic table include titanium (Ti), zirconium (Zr), and hafnium (Hi). Examples of metals in group 5 in the periodic table include vanadium (V), niobium (Nb), and tantalum (Ta). Examples of metals in group 6 in the periodic table include chromium (Cr), molybdenum (Mo), and tungsten (W). Examples of metals in group 7 in the periodic table include manganese (Mn), technetium (Tc), and rhenium (Re). Examples of metals in group 8 in the periodic table include iron (Fe), ruthenium (Ru), and osmium (Os). Examples of metals in group 9 in the periodic table include cobalt (Co), rhodium (Rh), and iridium (Ir). Examples of metals in group 10 in the periodic table include nickel (Ni), palladium (Pd), and platinum (Pt). In an embodiment of the present disclosure, the electrode layer preferably includes at least one type of metal selected from group 4 and group 9 in the periodic table, and more preferably includes a metal in group 9 in the periodic table. While the layer thickness of the electrode layer is not particularly limited, it is preferably 0.1 nm to 10 μm, more preferably 5 nm to 500 nm, and most preferably 10 nm to 200 nm. In an embodiment of the present disclosure, the electrode layer may be one composed of two or more layers that are different from one another in composition.

The method of forming the electrode layer is not particularly limited and may be a commonly known method. Specific examples of methods of forming the electrode layer or the other electrode layer include a dry method and a wet method. Examples of dry methods include sputtering, vacuum vapor deposition, and CVD. Examples of wet methods include screen printing and die coating.

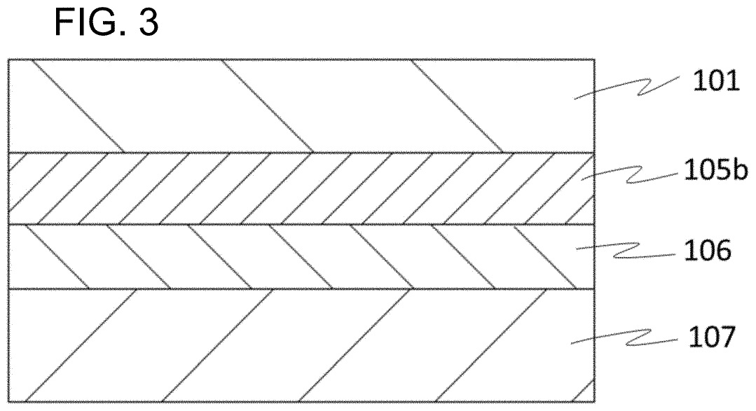

In step (3), the conductive substrate is laminated on the electrode layer, via a conductive bonding layer if desired, and the base substrate is removed using a commonly known method. By step (3), for example, the multilayer body as shown in FIG. 3 may be obtained. The multilayer body shown in FIG. 3 has the electrode layer 105b joined on the conductive substrate 107 via a conductive bonding layer 106, and the semiconductor layer 101 is laminated on the electrode layer 105b. Examples of methods of removing the base substrate include a method of removing by applying mechanical shock, a method of removing by using thermal stress through application of heat, a method of removing by applying vibration of ultrasonic waves etc., a method of removing by etching, a method of removing by grinding, a method of removing by such as a smart cut method in which heat treatment is performed after ion implantation, a method of removing by a laser lift-off method, and a method combining these methods.

The conductive bonding layer is not particularly limited as long as it is capable of joining the electrode layer and the conductive substrate together. Examples of materials composing the conductive bonding layer include a metal including at least one type selected from Al, Au, Pt, Ag, Ti, Ni, Bi, Cu, Ga, In, Pb, Sn, and Zn, metal oxides of these metals, and eutectic materials (e.g., Au—Sn). In an embodiment of the present disclosure, the conductive bonding layer preferably has a porous structure. When the conductive bonding layer has a porous structure, the conductive bonding layer preferably includes metal particles, more preferably includes metal particles containing at least one type of metal selected from Au, Pt, Ag, Ti, Ni, Bi, Cu, Ga, In, Pb, Sn, and Zn, and most preferably includes metal particles containing a precious metal. Examples of the precious metals include at least one type of metal selected from Au, Ag, Pt, Pd, Rh, Ir, Ru, and Os, and in an embodiment of the present disclosure, the precious metal is preferably Ag. In an embodiment of the present disclosure, the conductive bonding layer preferably includes a metal particle sintered body, and more preferably includes silver particle sintered body. By using such a preferable conductive bonding layer, better adhesion between the electrode layer and the conductive substrate may be achieved without the electrical characteristics of the semiconductor element being impaired. The conductive bonding layer may have a single layer or may have multiple layers. While the thickness of the conductive bonding layer is not particularly limited unless it interferes with the present disclosure, the thickness is preferably 10 nm to 200 μm and more preferably 30 nm to 50 μm. While the conductive bonding layer is usually amorphous, it may include an accessory component, such as a crystal. The method of forming the conductive bonding layer is not particularly limited and may be a commonly known application method.

The conductive substrate is not particularly limited as long as it has conductivity, is capable of supporting the semiconductor layer, and contains at least a first metal selected from the metals in group 11 in the periodic table and a second metal different from the first metal in coefficient of linear thermal expansion. Examples of the metal in group 11 in the periodic table include copper (Cu), silver (Ag), and gold (Au). In an embodiment of the present disclosure, the first metal is preferably copper (Cu). The second metal is not particularly limited as long as it is a metal different from the first metal in coefficient of linear thermal expansion. The “coefficient of linear thermal expansion” is measured in accordance with JIS R 3102 (1995). In an embodiment of the present disclosure, the second metal is also preferably a metal that is of the same type as the first metal and has a different coefficient of linear thermal expansion (e.g., a case where a layer including the first metal is usually a copper plating layer and a layer including the second metal is a low-linear-expansion copper plating layer). In the present disclosure, the second metal is preferably a metal in group 6 in the periodic table. Examples of the metal in group 6 in the periodic table include chromium (Cr), molybdenum (Mo), and tungsten (W). In an embodiment of the present disclosure, the metal in group 6 in the periodic table is preferably molybdenum (Mo). In an embodiment of the present disclosure, it is preferable that the second metal include a metal in group 6 in the periodic table, because then warpage of the semiconductor element is mitigated while the forward characteristics are further improved. In an embodiment of the present disclosure, when the conductive substrate includes molybdenum and copper, it is also preferable that a Cu—Mo composite substrate obtained by an impregnation method of impregnating a molybdenum compact with copper (hereinafter also simply referred to as a “Cu—Mo composite substrate”) be used as the conductive substrate. In an embodiment of the present disclosure, the conductive substrate may be one having a metal film on its surface. Examples of metals composing this metal film include one type or two or more types of metals selected from gallium, iron, indium, aluminum, vanadium, titanium, chromium, rhodium, nickel, cobalt, zinc, magnesium, calcium, silicon, yttrium, strontium, and barium.

In an embodiment of the present disclosure, the conductive substrate preferably has a multilayer structure in which at least one layer including the first metal and at least one layer including the second metal are laminated, and is more preferably formed by a multilayer structure in which at least one layer including molybdenum and at least one layer including copper are alternately laminated. in this case, the thickness of each layer is preferably 5 μm or larger and more preferably 10 μm or larger. By adopting such a preferable composition of the conductive substrate, it is possible to more favorably reduce the heat resistance of the semiconductor element while improving the forward characteristics of the semiconductor element. In an embodiment of the present disclosure, when the conductive substrate has the multilayer structure, it is preferable that a top layer and/or a bottom layer in the multilayer structure include the first metal, because then the heat dissipation property and the mounting efficiency of the semiconductor element may be further improved, and it is more preferable that the top layer and the bottom layer include the first metal. When the top layer and/or the bottom layer of the multilayer structure thus includes the first metal, the electrode layer and the conductive substrate are allowed to be joined together without using the conductive bonding layer, and warpage and heat resistance of the semiconductor element may be more effectively improved. Specifically, the electrode layer and the conductive substrate are allowed to be joined together in an industrially advantageous manner without using the conductive bonding layer by, for example, diffusion-bonding a copper-containing layer located on an outermost surface on the conductive substrate side in the electrode layer and a copper-containing layer located on an outermost surface on the electrode layer side in the multilayer structure of the conductive substrate. While the thickness of the conductive substrate is not particularly limited, it is preferable that the thickness be 200 μm or smaller because then better heat dissipation properties may be imparted without the electrical characteristics of the semiconductor element being impaired, and it is more preferable that the thickness be 100 μm or smaller. While the area of the conductive substrate is also not particularly limited, in an embodiment of the present disclosure, it is preferably substantially the same as the area of the semiconductor layer. Being substantially the same also includes, for example, a case where the area of the conductive substrate and the area of the semiconductor layer are the same, and includes a ratio of the area of the conductive substrate to the area of the semiconductor layer that is within a range of 0.9 to 1.4.

In an embodiment of the present disclosure, after step (3), the crystals of the crystalline semiconductor film may be grown again, or a different semiconductor layer, another electrode layer, etc. may be provided on the crystalline semiconductor film.

In an embodiment of the present disclosure, it is preferable that another electrode layer be further included on a surface facing a surface of the semiconductor layer on which the electrode layer is laminated. A multilayer structure in which the conductive substrate, the conductive bonding layer, the electrode layer, the semiconductor layer, and the other electrode layer are thus laminated in this order allows the semiconductor element to have better forward characteristics as a vertical device in which a current flows in the direction of the thickness of the semiconductor layer. The other electrode layer may be any layer having conductivity and is not particularly limited unless it interferes with the present disclosure. The material composing the other electrode layer may be a conductive inorganic material or may be a conductive organic material. In an embodiment of the present disclosure, the material of the other electrode is preferably metal. Suitable examples of the metals include at least one type of metal selected from group 8 to group 13 in the periodic table. Examples of metals in group 8 to group 10 in the periodic table include the metals respectively mentioned as examples of the metals in group 8 to group 10 in the periodic table in the description of the electrode layer. Examples of metals in group 11 in the periodic table include copper (Cu), silver (Ag), and gold (Au). Examples of metals in group 12 in the periodic table include zinc (ZN) and cadmium (Cd). Examples of metals in group 13 in the periodic table include aluminum (Al), gallium (Ga), and indium (In). In an embodiment of the present disclosure, the other electrode layer preferably includes at least one type of metal selected from the metals in group 11 and group 13 in the periodic table, and more preferably includes at least one type of metal selected from silver, copper, gold, and aluminum. While the layer thickness of the other electrode layer is not particularly limited, it is preferably 1 nm to 500 μm, more preferably 10 nm to 100 μm, and most preferably 0.5 μm to 10 μm.

The method of forming the other electrode layer is not particularly limited and may be a commonly known method. Specific examples of methods of forming the electrode layer or the other electrode layer include a dry method and a wet method. Examples of dry methods include sputtering, vacuum vapor deposition, and CVD. Examples of wet methods include screen printing and die coating.

The semiconductor element of the present disclosure is useful for various semiconductor elements, and is useful particularly for power devices. Semiconductor elements may be classified into horizontal elements (horizontal devices) in which an electrode is formed on a single side of a semiconductor layer and a current flows in a direction perpendicular to a film thickness direction of the semiconductor layer, and vertical elements (vertical devices) in which electrodes are respectively provided on both front and back surfaces of a semiconductor layer and a current flows in a film thickness direction of the semiconductor layer. In an embodiment of the present disclosure, while the semiconductor element is suitably usable for both a horizontal device and a vertical device, it is preferably used particularly for a vertical device. Examples of the semiconductor element include a Schottky barrier diode (SBD), a metal semiconductor field-effect transistor (MESFET), a high-electron-mobility transistor (HEMT), a metal-oxide semiconductor field-effect transistor (MOSFET), a static induction transistor (SIT), a junction field-effect transistor (JFET), an insulated gate bipolar transistor (IGBT), and a light-emitting diode. In an embodiment of the present disclosure, the semiconductor element is preferably an SBD, a MOSFET, an SIT, a JFET, or an IGBT, more preferably an SBD, a MOSFET, or an SIT, and most preferably an SBD.

In the following, suitable examples of the semiconductor element will be described using the drawings, but the present disclosure is not limited to these embodiments. In the semiconductor elements to be presented as examples below, unless they interfere with the present disclosure, yet another layer (e.g., an insulator layer, a semi-insulator layer, a conductor layer, a semiconductor layer, a buffer layer, and other intermediate layers) may be included or a buffer layer etc. may be omitted as appropriate.

(SBD)

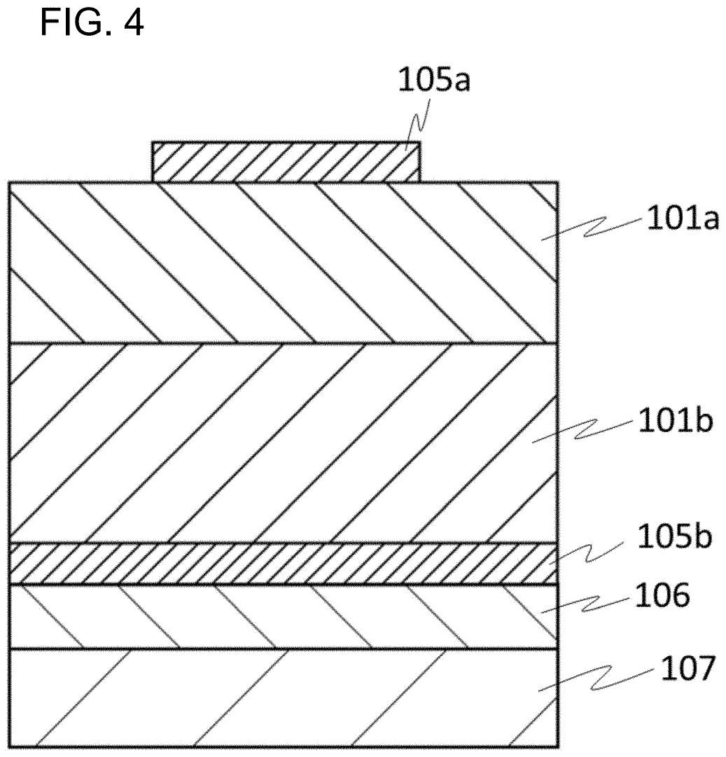

FIG. 4 shows an example of a Schottky barrier diode (SBD) according to the present disclosure. The SBD of FIG. 4 includes an n−-type semiconductor layer 101a, an n+-type semiconductor layer 101b, a conductive bonding layer 106, a conductive substrate 107, a Schottky electrode 105a, and an ohmic electrode 105b.

The materials of the Schottky electrode and the ohmic electrode may be commonly known electrode materials, and examples of the electrode materials include metals such as Al, Mo, Co, Zr, Sn, Nb, Fe, Cr, Ta, Ti, Au, Pt, V, Mn, Ni, Cu, Hf, W, Ir, Zn, In, Pd, Nd, and Ag and alloys of these metals; metal oxide conductive films such as tin oxide, zinc oxide, indium oxide, indium tin oxide (ITO), and indium zinc oxide (IZO); organic conductive compounds such as polyaniline, polythiophene, and polypyrrole; and mixtures of these materials.

The Schottky electrode and the ohmic electrode may be formed by, for example, a commonly known method such as a vacuum vapor deposition method or a sputtering method. More specifically, for example, to form a Schottky electrode, a layer made of Mo and a layer made of Al may be laminated, and the layer made of Mo and the layer made of Al may be patterned in a photolithographic way.

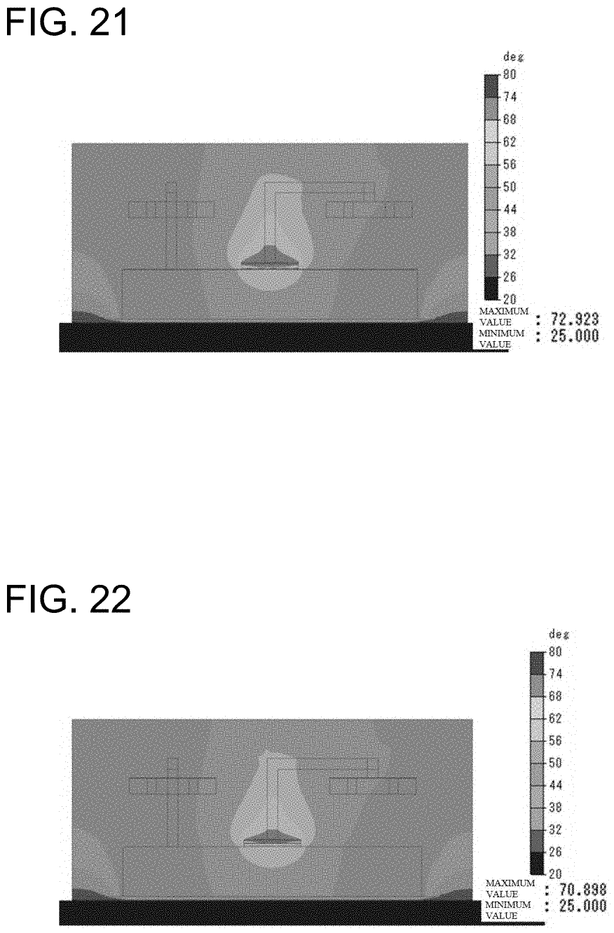

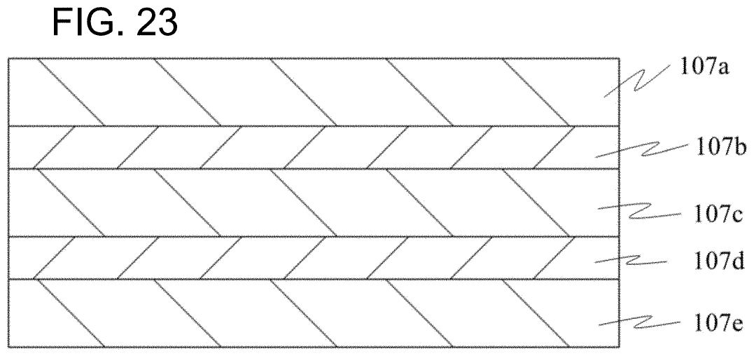

In an embodiment of the present disclosure, as the conductive substrate 107, a conductive substrate containing at least a first metal selected from the metals in group 11 in the periodic table and a second metal different from the first metal in coefficient of linear thermal expansion is used. In an embodiment of the present disclosure, as the conductive substrate 107, a conductive substrate including copper and a metal in group 6 in the periodic table is preferably used, and a conductive substrate including copper and molybdenum is preferably used, and a conductive substrate having a multilayer structure in which at least one layer including molybdenum and at least one layer including copper are laminated is more preferably used. By using a conductive substrate of such a preferable composition, it is possible to further reduce the heat resistance of the entire semiconductor element while improving the forward characteristics of the semiconductor element. FIG. 23 shows a preferable aspect of the conductive substrate. FIG. 23 shows a conductive substrate having a multilayer structure in which at least one layer including molybdenum and at least one layer including copper are laminated (hereinafter also referred to as a “Cu—Mo laminated substrate”). A first metal layer 107a, a third metal layer 107c, and a fifth metal layer 107e are composed of copper, and a second metal layer 107b and a fourth metal layer 107d are composed of molybdenum. Using an Si substrate, a Cu—Mo composite substrate (with the mass content of Mo being 70% and the mass content of Cu being 30%), and the Cu—Mo laminated substrate shown in FIG. 23 as conductive substrates, a simulation of heat resistance in a structure according to the SBD shown in FIG. 4 was conducted. The thickness of each conductive substrate was 100 μm. FIG. 20 shows a result of the case where the conductive substrate was the Si substrate. FIG. 21 shows a result of the case where the conductive substrate was the Cu—Mo composite substrate (with the mass content of Mo being 70% and the mass content of Cu being 30%). FIG. 22 shows the case where the conductive substrate was the Cu—Mo laminated substrate. As a result of this simulation, it was found that in the case where the Cu—Mo composite substrate or the Cu—Mo laminated substrate was used as the conductive substrate, the heat resistance of the semiconductor element was reduced compared with that in the case where the Si substrate was used. Further, it was found that in the case where the Cu—Mo laminated substrate was used, the heat resistance reducing effect was four or more times that in the case where the Cu—Mo composite substrate was used. These results demonstrate that using a substrate in which at least one layer including a metal in group 11 in the periodic table and at least one layer including molybdenum are laminated as the conductive substrate further improves the heat resistance of the semiconductor element using an oxide semiconductor (e.g., gallium oxide).

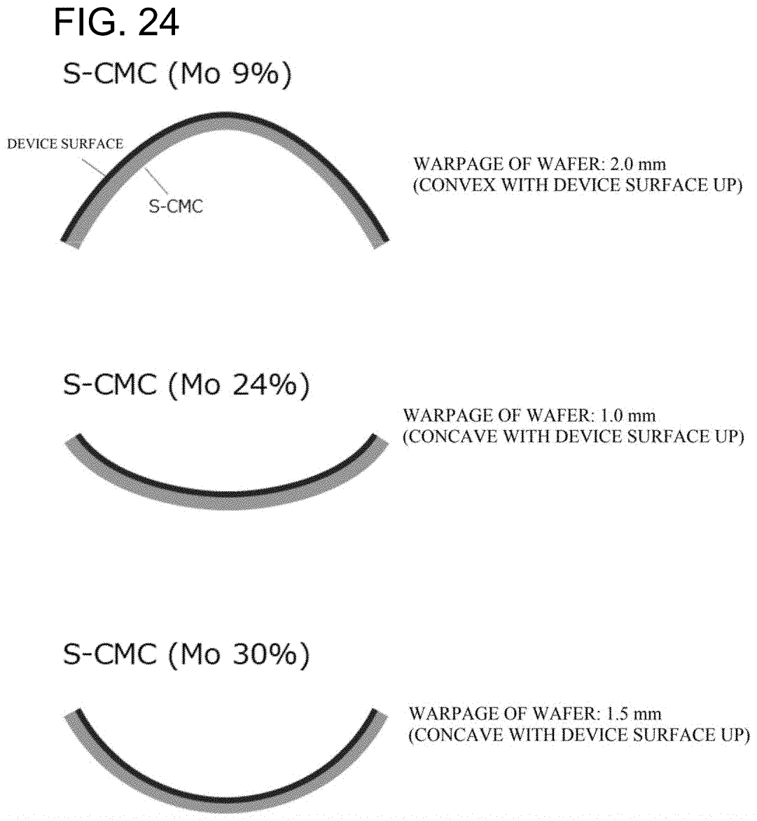

In the case where the Cu—Mo laminated substrate shown in FIG. 23 was used as the conductive substrate, the conductive elements were produced with the content of molybdenum in the conductive substrate set to 9%, 24%, and 30% as ratios by weight, and the amounts of warpage of the respective semiconductor elements were measured. FIG. 24 shows the results. As is clear from FIG. 24, a reduction in the amount of warpage of the entire semiconductor element is achievable through adjustment of the content of molybdenum in the conductive substrate. The content of molybdenum is appropriately adjustable through the thickness of the semiconductor layer in the semiconductor element, the thickness of the layer including a metal in group 11 in the periodic table, etc. Thus, when a conductive substrate including a first metal selected from the metals in group 11 in the periodic table and a second metal different from the first metal in coefficient of linear thermal expansion is used, warpage of the semiconductor element may be effectively reduced. In addition, warpage of the semiconductor element may be more favorably reduced by adjusting the thickness of each layer, and the material, etc. using the laminated substrate as shown in FIG. 23.

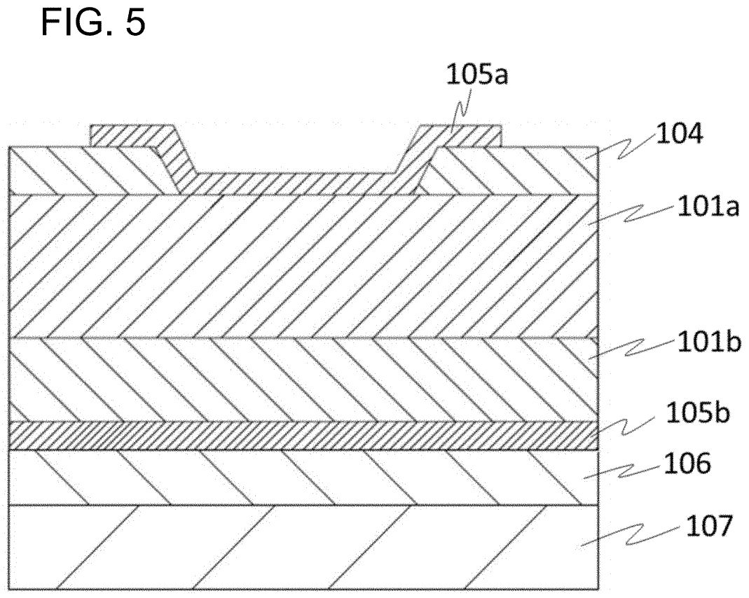

FIG. 5 shows an example of a Schottky barrier diode (SBD) according to the present disclosure. The SBD of FIG. 5 further includes an insulator layer 104 in addition to the composition of the SBD of FIG. 4. More specifically, it includes the n−-type semiconductor layer 101a, the n+-type semiconductor layer 101b, the conductive bonding layer 106, the conductive substrate 107, the Schottky electrode 105a, the ohmic electrode 105b, and the insulator layer 104.

Examples of materials of the insulator layer 104 include GaO, AlGaO, InAlGaO, AlInZnGaO₄, AlN, Hf₂O₃, SiN, SiON, Al₂O₃, MgO, GdO, SiO₂, and Si₃N₄, and in an embodiment of the present disclosure, the material preferably has a corundum structure. Using an insulator having a corundum structure for the insulator layer allows the functions of the semiconductor characteristics at an interface to be favorably exhibited. The insulator layer 104 is provided between the n−-type semiconductor layer 101 and the Schottky electrode 105a. The insulator layer may be formed by, for example, a commonly known method such as a sputtering method, a vacuum vapor deposition method, or a CVD method.

The formation, and the materials, etc. of the Schottky electrode and the ohmic electrode are similar to those in the case of the SBD of FIG. 4. That is, an electrode made of, for example, a metal such as Al, Mo, Co, Zr, Sn, Nb, Fe, Cr, Ta, Ti, Au, Pt, V, Mn, Ni, Cu, Hf, W, Ir, Zn, In, Pd, Nd, or Ag or an alloy of these metals; a metal oxide conductive film such as tin oxide, zinc oxide, indium oxide, indium tin oxide (ITO), or indium zinc oxide (IZO); or an organic conductive compound such as polyaniline, polythiophene, or polypyrrole; or a mixture of these materials may be formed using, for example, a commonly known method such as a sputtering method, a vacuum vapor deposition method, a pressure-bonding method, or a CVD method.

Compared with the SBD of FIG. 4, the SBD of FIG. 5 has even better insulation characteristics and has higher current controllability.

(MOSFET)

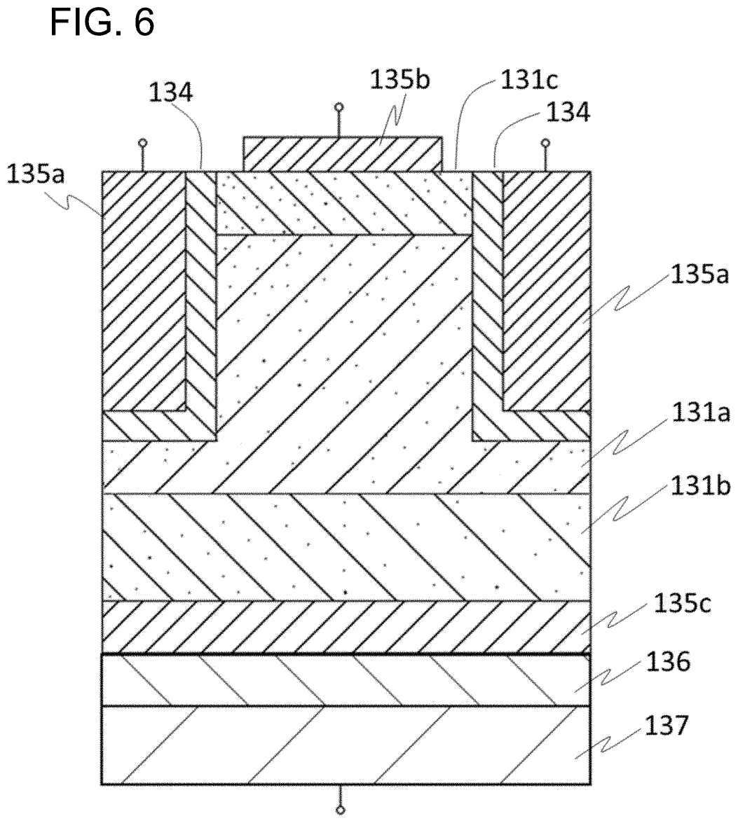

FIG. 6 shows an example of the case where the semiconductor element of the present disclosure is a MOSFET. The MOSFET of FIG. 6 is a trench-type MOSFET, and includes an n−-type semiconductor layer 131a, n+-type semiconductor layers 131b and 131c, a conductive bonding layer 136, a conductive substrate 137, a gate insulation film 134, a gate electrode 135a, a source electrode 135b, and a drain electrode 135c.

On the conductive substrate 137, the conductive bonding layer 136 having a thickness of, for example, 50 nm to 50 μm is formed. On the conductive bonding layer 136, the drain electrode 135c is formed. On the drain electrode 135c, the n+-type semiconductor layer 131b having a thickness of, for example, 100 nm to 100 μm is formed, and on the n+-type semiconductor layer 131b, the n−-type semiconductor layer 131a having a thickness of, for example, 100 nm to 100 μm is formed. Further, on the n−-type semiconductor layer 131a, the n+-type semiconductor layer 131c is formed, and on the n+-type semiconductor layer 131c, the source electrode 135b is formed.

Inside the n−-type semiconductor layer 131a and the n+-type semiconductor layer 131c, a plurality of trench grooves that extends through the n+-type semiconductor layer 131c and has such a depth as to reach an intermediate point in the n−-type semiconductor layer 131a are formed. Inside these trench grooves, the gate electrode 135a is formed by being embedded via the gate insulation film 134 having a thickness of, for example, 10 nm to 1 μm.

In an on-state of the MOSFET of FIG. 6, when a voltage is applied between the source electrode 135b and the drain electrode 135c and a positive voltage is given to the gate electrode 135a relative to the source electrode 135b, a channel layer is formed on a side surface of the n−-type semiconductor layer 131a, and electrons are injected into the n−-type semiconductor layer, which turns the MOSFET on. In an off-state, when the voltage of the gate electrode is set to 0V, the channel layer may not be formed, so that the n−-type semiconductor layer 131a enters a state of being filled with a depletion layer, which turns the MOSFET off.

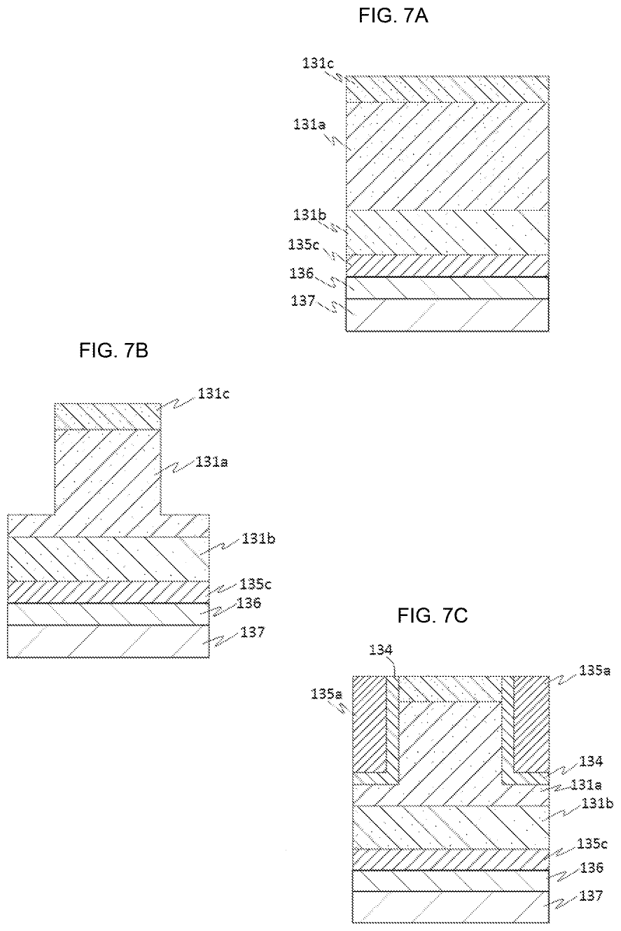

FIGS. 7A-7C show a part of the manufacturing process of the MOSFET of FIG. 6. For example, using the multilayer body as shown in FIG. 7A, an etching mask is provided in a predetermined region of the n−-type semiconductor layer 131a and the n+-type semiconductor layer 131c, and using the etching mask as a mask, anisotropic etching is further performed by a reactive ion etching method or the like. Thus, as shown in FIG. 7B, trench grooves having such a depth as to reach an intermediate point in the n−-type semiconductor layer 131a from the front surface of the n+-type semiconductor layer 131c are formed. Then, as shown in FIG. 7C, the gate insulation film 134 having a thickness of, for example, 50 nm to 1 μm is formed on side surfaces and bottom surfaces of the trench grooves using a commonly known method such as a thermal oxidation method, a vacuum vapor deposition method, a sputtering method, or a CVD method, and thereafter a gate electrode material such as polysilicon is formed in the trench grooves to a thickness not larger than the thickness of the n−-type semiconductor layer using a CVD method, a vacuum vapor deposition method, a sputtering method, or the like.

Then, the source electrode 135b and the drain electrode 135c are formed on the n+-type semiconductor layer 131c and the n+-type semiconductor layer 131b, respectively, using a commonly known method such as a vacuum vapor deposition method, a sputtering method, or a CVD method. Thus, a power MOSFET may be manufactured. The electrode materials of the source electrode and the drain electrode may each be a commonly known electrode material, and examples of the electrode materials include metals such as Al, Mo, Co, Zr, Sn, Nb, Fe, Cr, Ta, Ti, Au, Pt, V, Mn, Ni, Cu, Hf, W, Ir, Zn, In, Pd, Nd, or Ag and alloys of these metals; metal oxide conductive films such as tin oxide, zinc oxide, indium oxide, indium tin oxide (ITO), and indium zinc oxide (IZO); and organic conductive compounds such as polyaniline, polythiophene, and polypyrrole; and mixtures of these materials.

The MOSFET thus obtained has even better voltage resistance compared with a conventional trench-type MOSFET. While the example of a trench-type vertical MOSFET has been shown in FIG. 6, in an embodiment of the present disclosure, the semiconductor element is not limited thereto and applicable to various forms of MOSFETs. For example, the depth of the trench grooves of FIG. 6 may be increased to such a depth as to reach the bottom surface of the n−-type semiconductor layer 131a to thereby reduce the series resistance.

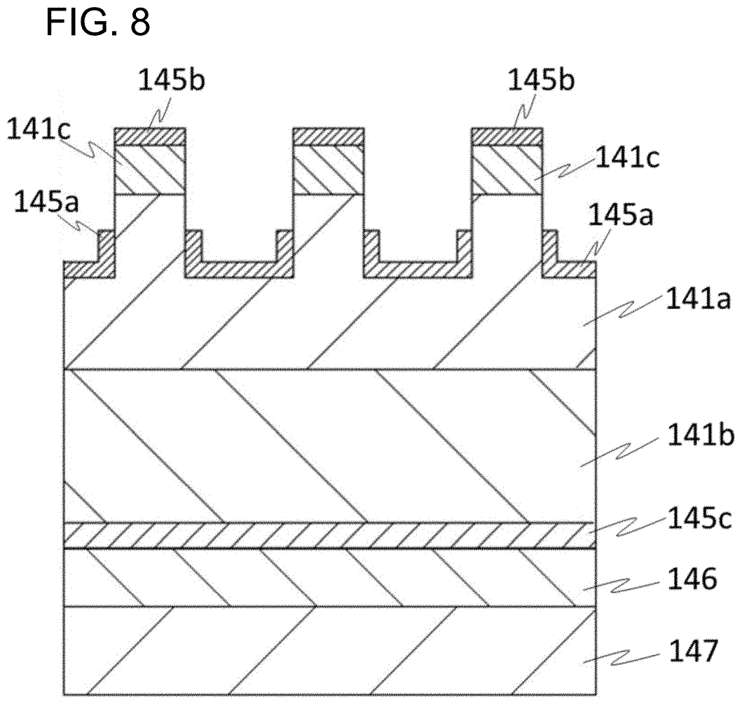

(SIT) FIG. 8 shows an example of the case where the semiconductor element of the present disclosure is an SIT. The SIT of FIG. 8 includes an n−-type semiconductor layer 141a, n+-type semiconductor layers 141b and 141c, a conductive bonding layer 146, a conductive substrate 147, a gate electrode 145a, a source electrode 145b, and a drain electrode 145c.

On the drain electrode 145c, the conductive support layer 147 having a thickness of, for example, 100 nm to 100 μm is formed, and on the conductive support layer 147, the conductive bonding layer 146 having a thickness of, for example, 50 nm to 50 μm is formed. On the conductive bonding layer 146, the n+-type semiconductor layer 141b having a thickness of, for example, 100 nm to 100 μm is formed, and on the n+-type semiconductor layer 141b, the n−-type semiconductor layer 141a having a thickness of, for example, 100 nm to 100 μm is formed. Further, on the n−-type semiconductor layer 141a, the n+-type semiconductor layer 141c is formed, and on the n+-type semiconductor layer 141c, the source electrode 145b is formed.

Inside the n−-type semiconductor layer 141a, a plurality of trench grooves that extends through the n+-type semiconductor layer 141c and has such a depth as to reach an intermediate point in the n−-type semiconductor layer 131a are formed. On the n−-type semiconductor layer 131a inside these trench grooves, the gate electrode 145a is formed. In an on-state of the SIT of FIG. 8, when a voltage is applied between the source electrode 145b and the drain electrode 145c and a positive voltage is given to the gate electrode 145a relative to the source electrode 145b, a channel layer is formed inside the n−-type semiconductor layer 141a, and electrons are injected into the n−-type semiconductor layer, which turns the SIT on. In an off-state, when the voltage of the gate electrode is set to 0V, the channel layer may not be formed, so that the n−-type semiconductor layer enters a state of being filled with a depletion layer, which turns the SIT off.

In an embodiment of the present disclosure, the SIT of FIG. 8 may be manufactured in the same manner as the MOSFET of FIGS. 7A-7C. More specifically, for example, an etching mask is provided in a predetermined region of the n−-type semiconductor layer 141a and the n+-type semiconductor layer 141c, and using the etching mask as a mask, anisotropic etching is performed by, for example, a reactive ion etching method. Thus, trench grooves having such a depth as to reach an intermediate point in the n−-type semiconductor layer 141a from the front surface of the n+-type semiconductor layer 141c are formed. Then, a gate electrode material such as polysilicon is formed in the trench grooves to a thickness not larger than the thickness of the n−-type semiconductor layer using a CVD method, a vacuum vapor deposition method, a sputtering method, or the like. The source electrode 145b and the drain electrode 145c are formed on the n+-type semiconductor layer 141c and the n+-type semiconductor layer 141b, respectively, using a commonly known method such as a vacuum vapor deposition method, a sputtering method, or a CVD method. Thus, an SIT may be manufactured. The electrode materials of the source electrode and the drain electrode may each be a commonly known electrode material, and examples of the electrode materials include metals such as Al, Mo, Co, Zr, Sn, Nb, Fe, Cr, Ta, Ti, Au, Pt, V, Mn, Ni, Cu, Hf, W, Ir, Zn, In, Pd, Nd, and Ag and alloys of these metals; metal oxide conductive films such as tin oxide, zinc oxide, indium oxide, indium tin oxide (ITO), and indium zinc oxide (IZO); and organic conductive compounds such as polyaniline, polythiophene, and polypyrrole; and mixtures of these materials.

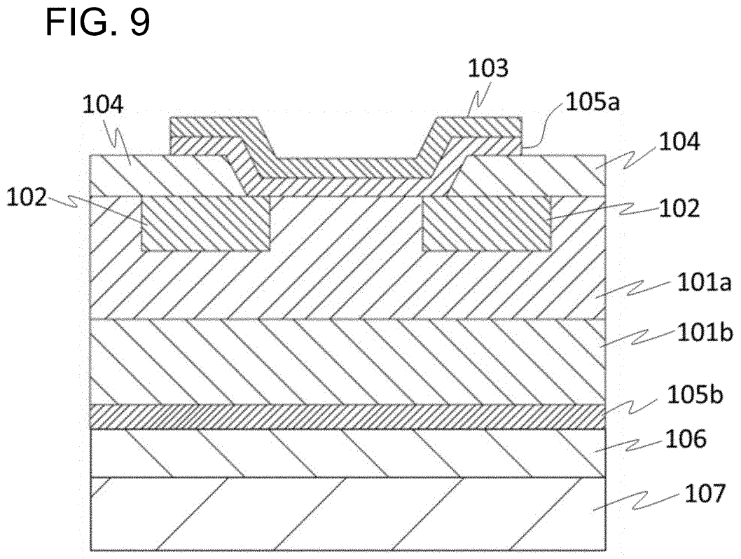

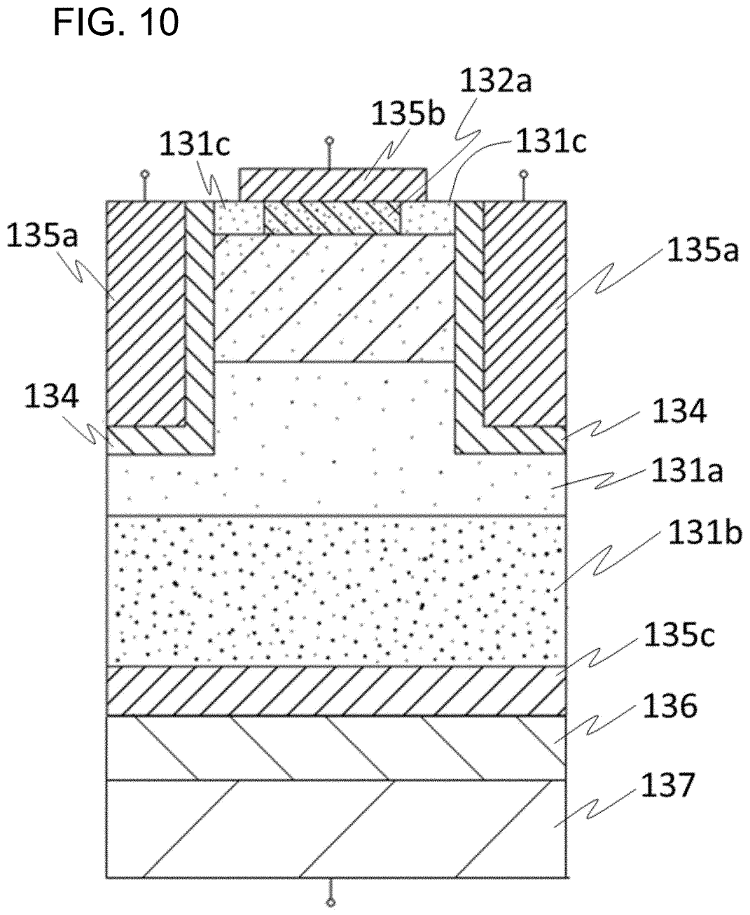

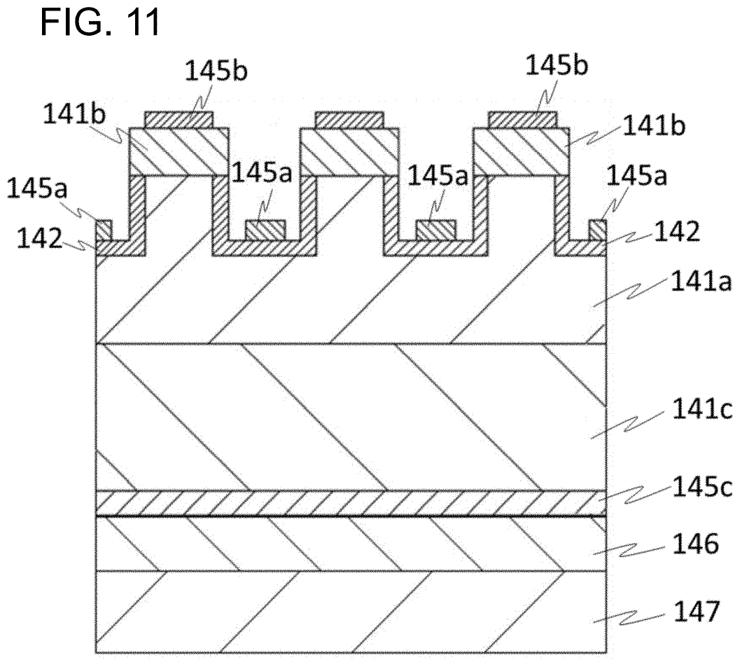

While the examples in which a p-type semiconductor is not used have been shown in the above examples, in an embodiment of the present disclosure, the semiconductor element is not limited thereto and a p-type semiconductor may be used. FIG. 9 to FIG. 11 show examples using a p-type semiconductor. These semiconductor elements may be manufactured in the same manner as in the above-described examples. The p-type semiconductor may be a material that is the same as an n-type semiconductor and includes a p-type dopant, or may be a different p-type semiconductor.

The semiconductor element is useful particularly for a power device. Examples of the semiconductor element include diodes (e.g., a PN diode, a Schottky barrier diode, and a junction barrier Schottky diode) and transistors (e.g., an MESFET). In particular, a diode is preferable and a Schottky barrier diode (SBD) is more preferable.

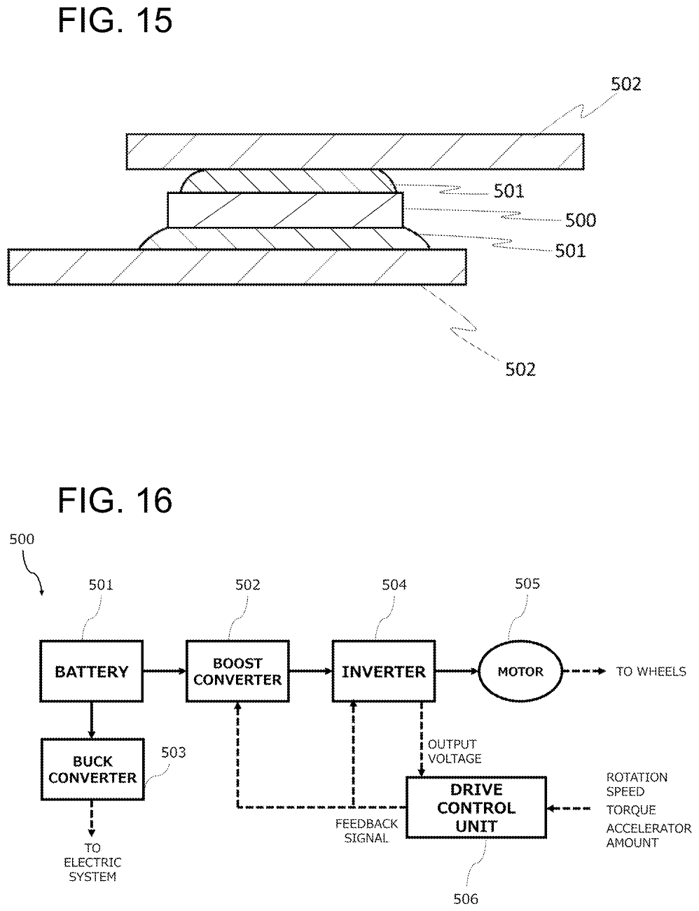

The semiconductor element in an embodiment of the present disclosure is suitably used as a semiconductor device by being further joined to a lead frame, a circuit board, a heat dissipation board, or the like with a joint member based on an ordinally method in addition to the above-described matters. In particular, the semiconductor element is suitably used as a power module, an inverter, or a converter, and is further suitably used for a semiconductor system using a power source device, for example. FIG. 15 shows a suitable example of the semiconductor device. In the semiconductor device of FIG. 15, both surfaces of a semiconductor element 500 are respectively joined to a lead frame, a circuit board, or a heat dissipation board 502 with solders 501. This composition may make the semiconductor device excellent in heat dissipation properties. In an embodiment of the present disclosure, it is preferable that the surroundings of the joint member, such as a solder, be sealed with resin.

In order to exhibit the functions described above, the semiconductor film and/or the semiconductor device of the disclosure described above can be applied to a power converter such as an inverter or a converter.

More specifically, it can be applied as a diode incorporated in the inverter or converter, a thyristor, a power transistor, an IGBT (Insulated Gate Bipolar Transistor), a MOSFET (Metal-Oxide-Semiconductor Field Effect Transistor or the like as a switching element.

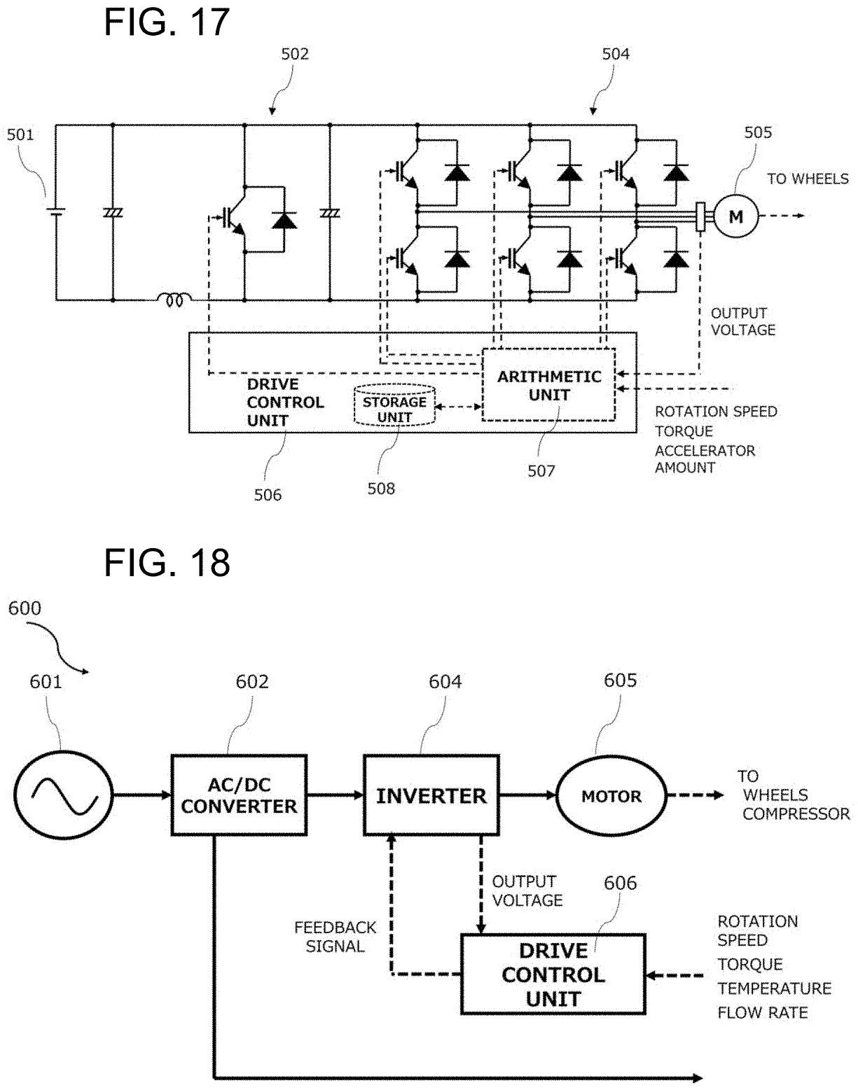

FIG. 16 is a block diagram illustrating an exemplary control system applying a semiconductor device according to an embodiment of the disclosure, and FIG. 17 is a circuit diagram of the control system particularly suitable for applying to a control system of an electric vehicle.

As shown in FIG. 16, the control system 500 includes a battery (power supply) 501, a boost converter 502, a buck converter 503, an inverter 504, a motor (driving object) 505, a drive control unit 506, which are mounted on an electric vehicle.

The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle.

The boost converter 502 is, for example, a voltage converter in which a chopper circuit is mounted, and can step-up DC voltage of, for example, 200V supplied from the battery 501 to, for example, 650V by switching operations of the chopper circuit. The step-up voltage can be supplied to a traveling system such as a motor.

The buck converter 503 is also a voltage converter in which a chopper circuit is mounted, and can step-down DC voltage of, for example, 200V supplied from the battery 501 to, for example, about 12V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505.

The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506.

The output voltage value of the inverter 504 is also input to the drive control unit 506 at the same time.

The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements.

The AC voltage supplied to the motor 505 from the inverter 504 is thus corrected instantaneously, and the driving control of the electric vehicle can be executed accurately. Safety and comfortable operation of the electric vehicle is thereby realized.

In addition, it is also possible to control the output voltage to the inverter 504 by providing a feedback signal from the drive control unit 506 to the boost converter 502.

FIG. 17 is a circuit configuration excluding the buck converter 503 in FIG. 16, in other words, a circuit configuration showing a configuration only for driving the motor 505.

As shown in the FIG. 17, the semiconductor device of the disclosure is provided for switching control by, for example, being applied to the boost controller 502 and the inverter 504 as a Schottky barrier diode.

The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504.

The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 17, an arithmetic unit 507 including a CPU (Central Processing Unit) and a storage unit 508 including a nonvolatile memory are provided in the drive control unit 506.

Signal input to the drive control unit 506 is given to the arithmetic unit 507, and a feedback signal for each semiconductor element is generated by performing the programmed operation as necessary.

The storage unit 508 temporarily holds the calculation result by the calculation unit 507, stores physical constants and functions necessary for driving control in the form of a table, and outputs the physical constants, functions, and the like to the arithmetic unit 507 as appropriate.

The arithmetic unit 507 and the storage unit 508 can be provided by a known configuration, and the processing capability and the like thereof can be arbitrarily selected.

As shown in Figs. A and B, a diode and a switching element such as a thyristor, a power transistor, an IGBT, a MOSFET and the like is employed for the switching operation of the boost converter 502, the buck converter 503 and the inverter 504 in the control system 500.

The use of gallium oxide (Ga₂O₃) specifically corundum-type gallium oxide (α-Ga₂O₃) as its materials for these semiconductor devices greatly improves switching properties.

Further, extremely outstanding switching performance can be expected and miniaturization and cost reduction of the control system 500 can be realized by applying a semiconductor film or a semiconductor device of the disclosure.

That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the semiconductor device of the disclosure, but can be applied to a control system for any applications such as to step-up and step-down the power from a DC power source, or convert the power from a DC to an AC. It is also possible to use a power source such as a solar cell as a battery.

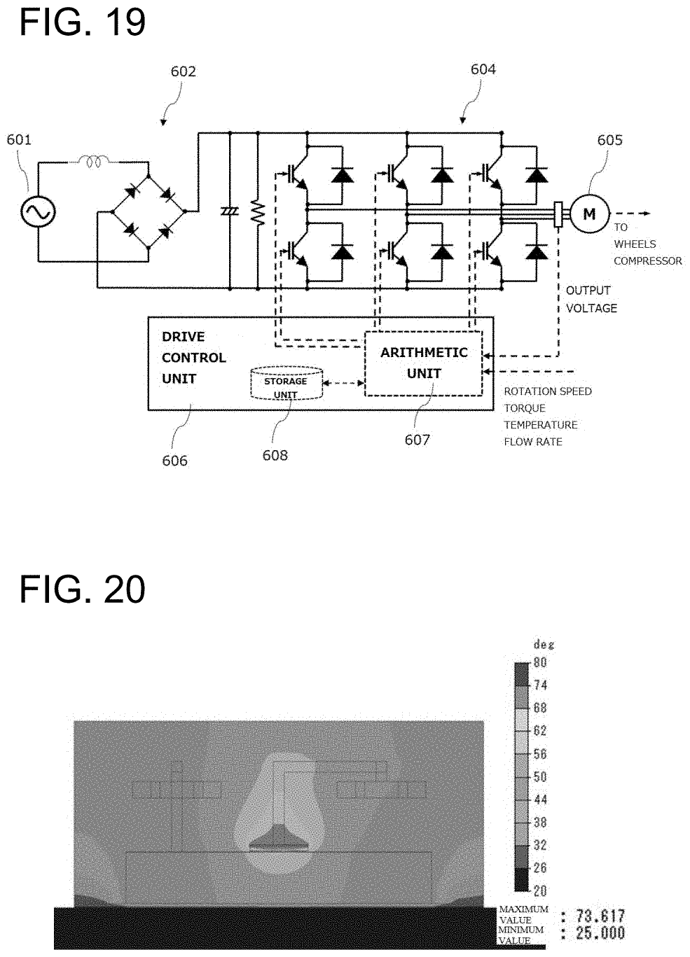

FIG. 18 is a block diagram illustrating another exemplary control system applying a semiconductor device according to an embodiment of the disclosure, and FIG. 19 is a circuit diagram of the control system suitable for applying to infrastructure equipment and home appliances or the like operable by the power from the AC power source.

As shown in FIG. 18, the control system 600 is provided for inputting power supplied from an external, such as a three-phase AC power source (power supply) 601, and includes an AC/DC converter 602, an inverter 604, a motor (driving object) 605 and a drive control unit 606 that can be applied to various devices described later.

The three-phase AC power supply 601 is, for example, a power plant (such as a thermal, hydraulic, geothermal, or nuclear plant) of an electric power company, whose output is supplied as an AC voltage while being downgraded through substations.

Further, the three-phase AC power supply 601 is installed in a building or a neighboring facility in the form of a private power generator or the like for supplying the generated power via a power cable.

The AC/DC converter 602 is a voltage converter for converting AC voltage to DC voltage. The AC/DC converter 602 converts AC voltage of 100V or 200V supplied from the three-phase AC power supply 601 to a predetermined DC voltage.

Specifically, AC voltage is converted by a transformer to a desired, commonly used voltage such as 3.3V, 5V, or 12V.

When the driving object is a motor, conversion to 12V is performed.

It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605.

Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC inverter 602. In that case the inverter 604 becomes unnecessary in the control system 600, and a DC voltage from the AC/DC inverter 602 is supplied to the driving object directly as shown in FIG. 18.

Here, DC voltage of 3.3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606.

At the same time, the output voltage value of the inverter 604 is also input to the drive control unit 606.

Based on these measured signals, the drive control unit 606 provides a feedback signal to the inverter 604 thereby controls switching operations by the switching element of the inverter 604.

The AC voltage supplied to the motor 605 from the inverter 604 is thus corrected instantaneously, and the operation control of the driving object can be executed accurately. Stable operation of the driving object is thereby realized.

In addition, when the driving object can be driven by a DC voltage, as described above, feedback control of the AC/DC controller 602 is possible in place of feedback control of the inverter.

FIG. 19 shows the circuit configuration of FIG. 18.

As shown in FIG. 19, the semiconductor device of the disclosure is provided for switching control by, for example, being applied to the AC/DC converter 602 and the inverter 604 as a Schottky barrier diode.

The AC/DC converter 602 has, for example, a circuit configuration in which Schottky barrier diodes are arranged in a bridge-shaped, to perform a direct-current conversion by converting and rectifying the negative component of the input voltage to a positive voltage.

Schottky barrier diodes can also be applied to a switching circuit in IGBT of the inverter 604 to perform switching control.

The voltage can be stabilized by interposing a capacitor (such as an electrolytic capacitor) between the AC/DC converter 602 and the inverter 604.

As indicated by a dotted line in FIG. 19, an arithmetic unit 607 including a CPU and a storage unit 608 including a nonvolatile memory are provided in the drive control unit 606.

Signal input to the drive control unit 606 is given to the arithmetic unit 607, and a feedback signal for each semiconductor element is generated by performing the programmed operation as necessary.

The storage unit 608 temporarily holds the calculation result by the arithmetic unit 607, stores physical constants and functions necessary for driving control in the form of a table, and outputs the physical constants, functions, and the like to the arithmetic unit 607 as appropriate.

The arithmetic unit 607 and the storage unit 608 can be provided by a known configuration, and the processing capability and the like thereof can be arbitrarily selected.

In such a control system 600, similarly to the control system 500 shown in Figs. A and B, a diode or a switching element such as a thyristor, a power transistor, an IGBT, a MOSFET or the like is also applied for the purpose of the rectification operation and switching operation of the AC/DC converter 602 and the inverter 604. Switching performance can be improved by the use of gallium oxide (Ga₂O₃), particularly corundum-type gallium oxide (α-Ga₂O₃), as materials for these semiconductor elements.

Further, extremely outstanding switching performance can be expected and miniaturization and cost reduction of the control system 600 can be realized by applying a semiconductor film or a semiconductor device of the disclosure.

That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

Although the motor 605 has been exemplified in Figs. C and D, the driving object is not necessarily limited to those that operate mechanically. Many devices that require an AC voltage can be a driving object.

It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

### EXAMPLE

While examples of the present disclosure will be described below, the present disclosure is not limited to these examples.

### Example 1

1. Formation of N−-Type Semiconductor Layer

1-1. Deposition Device

A mist CVD device 1 used in this example will be described using FIG. 12. The mist CVD device 1 includes: a carrier gas source 2a that supplies a carrier gas; a flow control valve 3a that adjusts the flow rate of the carrier gas sent from the carrier gas source 2a; a carrier gas (dilution) source 2b that supplies a carrier gas (dilution); a flow control valve 3b that adjusts the flow rate of the carrier gas (dilution) sent from the carrier gas (dilution) source 2b; a mist generation source 4 that houses a raw material solution 4a; a container 5 in which water 5a is held; an ultrasonic transducer 6 mounted on a bottom surface of the container 5; a deposition chamber 7; a supply pipe 9 that connects the mist generation source 4 to the deposition chamber 7; a hot plate 8 installed inside the deposition chamber 7; and a discharge port 11 through which mist, droplets, and exhaust gas after a thermal reaction are discharged. A substrate 10 is installed on the hot plate 8.

1-2. Formation of Crystalline Oxide Semiconductor Film

Using the mist CVD device shown in FIG. 12, an n−-type semiconductor layer was formed on a sapphire substrate (the substrate 10).

1-3. Evaluation

When the phase of the film obtained in 1-2. was identified using an XRD diffracting device, the obtained film was α-Ga₂O₃.

2. Formation of N+-Type Semiconductor Layer

An n+-type semiconductor layer was formed on an n−-type semiconductor layer in the same manner as in 1-2. except that tin was used as a dopant. For the obtained film, the phase of the film was identified using an XRD diffracting device, and the obtained film was α-Ga₂O₃.

3. Formation of Ohmic Electrode

A Ti layer and an Au layer were each laminated by sputtering on the n+-type semiconductor layer of the multilayer body obtained in 2. The thickness of the Ti layer was 70 nm and the thickness of the Au layer was 30 nm.

4. Lamination of Conductive Substrate

On the ohmic electrode of the multilayer body obtained in 3., a Cu—Mo composite substrate (with the mass content of Mo being 70% and the mass content of Cu being 30%) was laminated via a conductive bonding layer formed by a silver particle sintered body. The thickness of the conductive substrate was 200 μm.

5. Removal of Substrate

The sapphire substrate was removed from the multilayer body obtained in 4.

6. Formation of Schottky Electrode

On the second n−-type semiconductor layer of the multilayer body obtained in 5., a Co film (100 nm thick), a Ti film (50 nm), and an Al film (5 μm thick) were each formed by EB vapor deposition to form a Schottky electrode.

### Comparative Example 1

An SBD was produced in accordance with Example 1, except that an Si substrate was used as the conductive substrate.

(Evaluation of Electrical Characteristics)

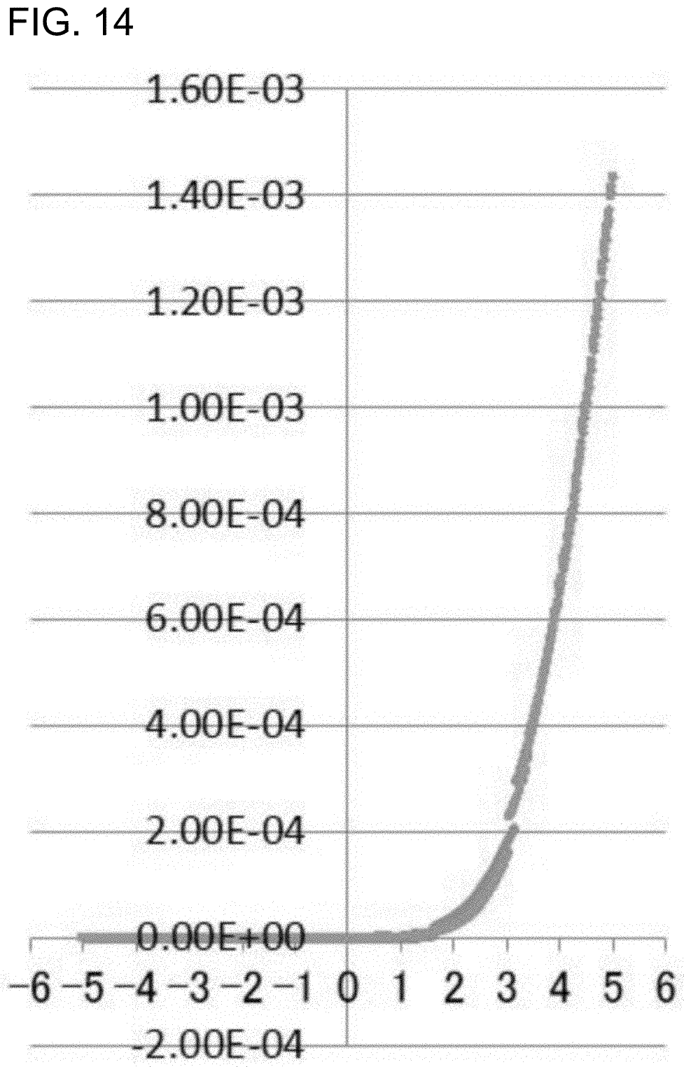

The semiconductor elements (SBDs) obtained in Example 1 and Comparative Example 1 were evaluated for their IV characteristics. FIG. 13 and FIG. 14 show the results. FIG. 13 and FIG. 14 indicate that the Schottky barrier diode of Example 1 has excellent electrical characteristics. Also in the case where the Cu—Mo laminated substrate shown in FIG. 23 is used as the conductive substrate, electrical characteristics equivalent to those of Example 1 are obtained.

The semiconductor element of the present disclosure is usable in all the fields of semiconductors (e.g., compound semiconductor electronic devices), electronic components and electrical equipment components, optical and electronic photograph-related devices, industrial members, etc., and is useful particularly for power devices.

The embodiments of the present invention are exemplified in all respects, and the scope of the present invention includes all modifications within the meaning and scope equivalent to the scope of claims.

### REFERENCE SIGNS LIST

1 Deposition device (mist CVD device)
2a Carrier gas source
2b Carrier gas (dilution) source
3a Flow control valve
3b Flow control valve
4 Mist generation source
4a Raw material solution
4b Raw material fine particle
5 Container
5a Water
6 Ultrasonic transducer
7 Deposition chamber
8 Hot plate
9 Supply pipe
10 Substrate
101 Semiconductor layer
101a N−-type semiconductor layer
101b N+-type semiconductor layer
102 P-type semiconductor layer
103 Metal layer
104 Insulator layer
105 Electrode layer
105a Schottky electrode (another electrode layer)
105b Ohmic electrode (electrode layer)
106 Conductive bonding layer
107 Conductive substrate
107a First metal layer
107b Second metal layer
107c Third metal layer
107d Fourth metal layer
107e Fifth metal layer
108 Base substrate
131a N−-type semiconductor layer
131b First n+-type semiconductor layer
131c Second n+-type semiconductor layer
132 P-type semiconductor layer
134 Gate insulation film
135a Gate electrode
135b Source electrode
135c Drain electrode
136 Conductive bonding layer
137 Conductive substrate
141a N−-type semiconductor layer
141b First n+-type semiconductor layer
141c Second n+-type semiconductor layer
142 P-type semiconductor layer
145a Gate electrode
145b Source electrode
145c Drain electrode
146 Conductive bonding layer
147 Conductive substrate
500 control system
501 battery (power supply)
502 boost converter
503 buck converter
504 inverter
505 motor (driving object)
506 drive control unit
507 arithmetic unit
508 storage unit
600 control system
601 three-phase AC power supply
602 AC/DC converter
604 inverter
605 motor (driving object)
606 drive control unit
607 arithmetic unit
608 storage unit

What is claimed is:

1. A semiconductor element comprising at least:
a semiconductor layer including a crystalline oxide semiconductor as a major component;
an electrode layer laminated on the semiconductor layer; and
a conductive substrate laminated on the electrode layer directly or with another layer in between, the conductive substrate containing at least a first metal selected from the metals in group 11 in the periodic table and a second metal different from the first metal in coefficient of liner thermal expansion.

2. The semiconductor element according to claim 1, wherein the first metal is copper.

3. The semiconductor element according to claim 1, wherein the second metal includes a metal in group 6 in the periodic table.

4. The semiconductor element according to claim 3, wherein the metal in group 6 in the periodic table is molybdenum.

5. The semiconductor element according to claim 1, wherein the conductive substrate has a multilayer structure in which at least one layer including the first metal and at least one layer including the second metal are laminated.

6. The semiconductor element according to claim 5, wherein a top layer and/or a bottom layer of the multilayer structure includes the first metal.

7. The semiconductor element according to claim 1, wherein the crystalline oxide semiconductor includes at least one metal selected from aluminum, indium, and gallium.

8. The semiconductor element according to claim 1, wherein the crystalline oxide semiconductor includes at least gallium.

9. The semiconductor element according to claim 1, further comprising another electrode layer on a surface facing a surface of the semiconductor layer on which the electrode layer is laminated.

10. The semiconductor element according to claim 1, wherein the semiconductor element is a power device.

11. A semiconductor device formed by joining at least a semiconductor element to a lead frame, a circuit board, or a heat dissipation substrate by means of a joint member, wherein the semiconductor element is the semiconductor element according to claim 1.

12. A power converter that uses the semiconductor device according to claim 11.

13. A control system that uses the semiconductor device according to claim 11.
